(19) United States
(12) Patent Application Publication
(10) Pub. No.: US 2026/0266898 A1
(43) Pub. Date: Sep. 10, 2026

(54) TRANSFER SYSTEM AND TRANSFER METHOD

(71) Applicant: Tokyo Electron Limited, Tokyo (JP)

(72) Inventors: Yusuke NATORI, Yamanashi (JP); Tomoya ENDO, Yamanashi (JP); Jun FUJIHARA, Yamanashi (JP); Takaaki HOSHINO, Yamanashi (JP); Yuki ISHIDA, Yamanashi (JP)

(21) Appl. No.: 19/666,489

(22) Filed: May 4, 2026

Related U.S. Application Data
(63) Continuation of application No. PCT/JP2024/039220, filed on Nov. 5, 2024.

(30) Foreign Application Priority Data
Nov. 17, 2023 (JP) 2023-196164
Jul. 9, 2024 (JP) 2024-110534

(51) Int. Cl. G01R 31/28

(52) U.S. Cl. CPC G01R 31/2893; G01R 31/2891

(57) ABSTRACT

A transfer system includes a transfer module extending along a first direction, a plurality of processing modules connected to the transfer module and provided along a direction in which the transfer module extends, and a loader module connected to the transfer module and extending along a second direction orthogonal to the first direction. The loader module includes a main housing having a load port configured to load a transfer target into the loader module, and a sub-housing formed separately from the main housing and smaller than the main housing and connected to the transfer module in the second direction of the main housing. The second direction is a direction parallel to a carrier conveyance line for conveying a carrier configured to accommodate the transfer target.

### CROSS-REFERENCE TO RELATED APPLICATIONS

This application is a continuation application of International Application No. PCT/JP2024/039220 filed on November 5, 2024, and designating the U.S., which is based upon and claims priority to Japanese Patent Application No. 2023-196164 filed on November 17, 2023 and Japanese Patent Application No. 2024-110534 filed on July 9, 2024, the entire contents of which are incorporated herein by reference.

### BACKGROUND

### Technical Field

The present disclosure relates to a transfer system and a transfer method.

### 2. Description of Related Art

Japanese Unexamined Patent Application Publication No. H6-69295 (hereinafter "Patent Document 1") discloses a transfer system (probe system) in which a carrier accommodating a plurality of wafers, serving as transfer targets, is conveyed by a transport mechanism to transfer the wafers to respective processing modules (probe devices). This transfer system includes a loader module (handoff mechanism) provided for each of the plurality of processing modules. Each loader module receives wafers from the carrier conveyed by the transport mechanism and transfers the wafers to the corresponding processing module, where each processing module inspects the wafers.

### SUMMARY

According to an aspect of the present disclosure, there is provided a transfer system including a transfer module extending along a first direction, a plurality of processing modules connected to the transfer module and provided along a direction in which the transfer module extends, and a loader module connected to the transfer module and extending along a second direction orthogonal to the first direction. The loader module includes a main housing having a load port configured to load a transfer target into the loader module, and a sub-housing formed separately from the main housing and smaller than the main housing and connected to the transfer module in the second direction of the main housing. The second direction is a direction parallel to a carrier conveyance line for conveying a carrier configured to accommodate the transfer target.

### BRIEF DESCRIPTION OF THE DRAWINGS

FIG. 1 is a plan view illustrating an example of a worksite where a transfer system according to an embodiment is installed;

FIG. 2 is an enlarged plan view illustrating a substrate inspection unit and an overhead hoist transport device;

FIG. 3 is a further enlarged plan view illustrating a loader module and an inspection device;

FIG. 4 is a perspective view illustrating a main housing and a sub-housing of a loader module;

FIG. 5 is an enlarged perspective view illustrating the negative X-axis side of a transfer module and an inspection device;

FIG. 6A is a plan view illustrating a function of adjusting a length of the transfer module in an extension direction;

FIG. 6B is an enlarged plan view illustrating a connection of divided frames;

FIG. 6C is an enlarged side view illustrating a connection of divided frames;

FIG. 7A is a front view illustrating an energy management device;

FIG. 7B is a side view illustrating the energy management device; and

FIG. 8 is a flowchart illustrating a transfer method according to an embodiment.

### DETAILED DESCRIPTION

The present disclosure provides a technique capable of efficiently transferring transfer targets to a plurality of processing modules and improving space efficiency.

Hereinafter, an embodiment for carrying out the present disclosure will be described with reference to the drawings. In each of the drawings, the same components are denoted by the same reference numerals and redundant descriptions may be omitted.

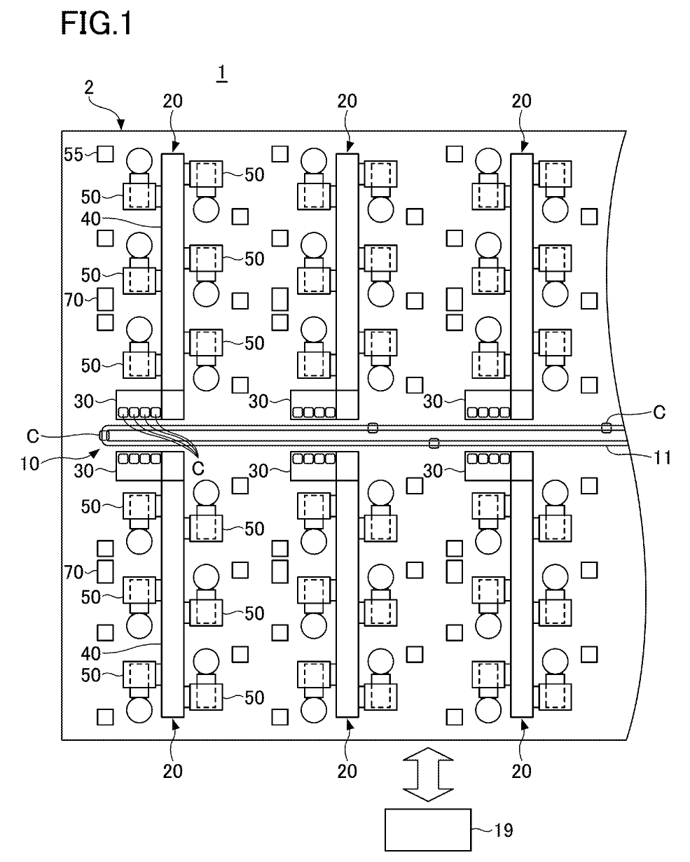

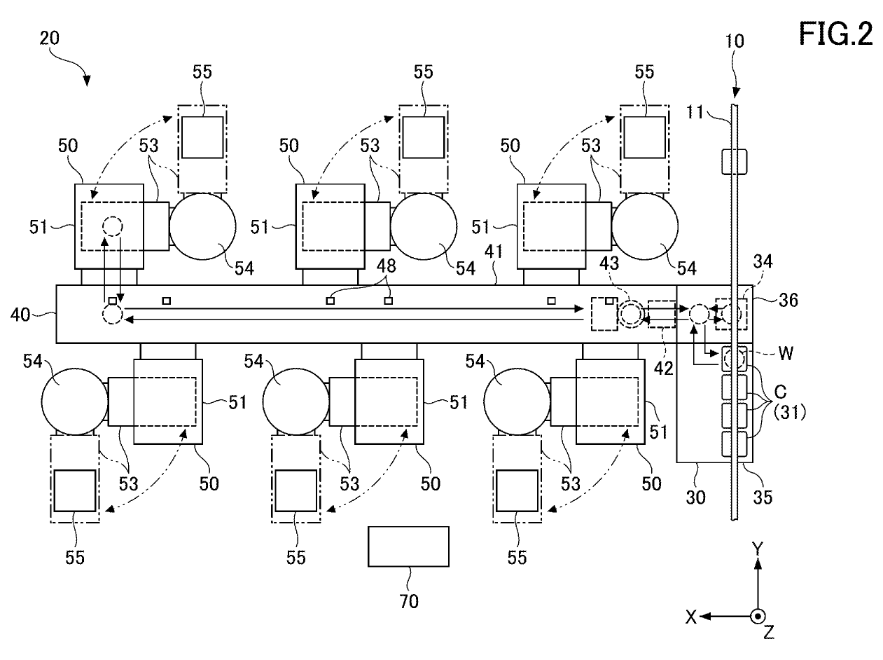

FIG. 1 is a plan view illustrating an example of a worksite 2 in which a transfer system 1 according to an embodiment is installed. As illustrated in FIG. 1, the transfer system 1 is constructed in a worksite 2, such as a facility for manufacturing semiconductor devices or a facility for inspecting semiconductor devices. In the present embodiment, the transfer system 1 for transferring a substrate W, which serves as a transfer target, to an inspection device 50 for inspecting the substrate W (see FIG. 2) will be described. One example of a substrate W serving as an inspection target of the inspection device 50 may be a wafer in which a plurality of semiconductor devices which are device under tests (DUT) are arranged in a matrix. The substrate W is not limited to a wafer and may be, for example, a carrier having a semiconductor device, a glass substrate, a single chip, an electronic circuit board, or the like.

The transfer system 1 includes an overhead hoist transport device (OHT) 10 for conveying a carrier C, and a plurality of substrate inspection units 20. The carrier C is a container capable of accommodating a plurality of (for example, 25) substrates W. An example of the carrier C is a front opening unified pod (FOUP) having one openable and closable side wall. The overhead hoist transport device 10 conveys the carrier C in a state in which a plurality of substrates W are accommodated or in an empty state.

The overhead hoist transport device 10 includes a rail 11 fixed to the ceiling of the worksite 2, and a hoist mechanism (not illustrated) configured to travel along the rail 11 while holding the carrier C and raise and lower the carrier C. For example, the hoist mechanism has a function of holding the carrier C in a suspended state and raising and lowering the carrier C by a belt. The overhead hoist transport device 10 also includes a control device 19 for controlling the operation of the overhead hoist transport device 10 at an appropriate position of the worksite 2.

In FIG. 1, the rail 11 is illustrated spaced apart from each substrate inspection unit 20 for ease of understanding, but in practice the rail 11 is installed to extend over a loader module 30 of each substrate inspection unit 20 (see also FIG. 2). The hoist mechanism moving along the rail 11 moves directly above the loader module 30 of a target substrate inspection unit 20 and lower the carrier C, thereby automatically placing the carrier C in the loader module 30. The hoist mechanism also moves directly above the carrier C of the loader module 30 to hold and raise the carrier C, thereby unloading the carrier C from the substrate inspection unit 20.

For example, the rail 11 forms a carrier conveyance line that extends along the longitudinal direction of the worksite 2 at a central position center in the transverse direction, and turns back at one longitudinal end, and then extends again in the longitudinal direction at the transverse center of the worksite 2. In FIG. 1, the longitudinal direction of the worksite 2 corresponds to the horizontal direction of the drawing sheet, while the transverse direction of the worksite 2 corresponds to the vertical direction of the drawing sheet. By arranging the rail 11 at the transverse center as described herein, the overhead hoist transport device 10 can efficiently convey the plurality of carrier C to all the substrate inspection units 20 in the worksite 2 while shortening a travel distance of the plurality of carriers C.

The rail 11 may have an endless configuration that allows a plurality of hoist mechanisms to circulate along the rail 11. The overhead hoist transport device 10 includes, for example, a carrier exchanger (not illustrated) configured to collect or exchange the carrier C at a longitudinal end of the rail 11 having the endless configuration. The overhead hoist transport device 10 may include a point rail branched at an intermediate position of the rail 11, and the carrier exchanger may be provided on the point rail.

The control device 19 of the overhead hoist transport device 10 is a computer including a processor (not illustrated), a memory, an input/output interface, a communication interface, and the like. The processor is a combination of one or more of a CPU (central processing unit), a GPU (graphics processing unit), an ASIC (application specific integrated circuit), an FPGA (field-programmable gate array), a circuit composed of a plurality of discrete semiconductors, and the like, and executes a program stored in the memory. The memory includes a main storage device composed of a semiconductor memory, and an auxiliary storage device composed of a disk, a drive, a semiconductor memory (flash memory), and the like.

The control device 19 moves the hoist mechanism to a target position on the rail 11, and controls the raising, holding, detaching, and the like of the carrier C. The control device 19 also controls the carrier exchanger to collect and exchange the carrier C, and manages the state of each substrate W accommodated in the carrier C. The control device 19 may be installed at a management computer for managing the entire transfer system 1 (worksite 2).

On the other hand, each substrate inspection unit 20 of the transfer system 1 is installed to extend along a direction perpendicular to an extension direction of the rail 11 installed at the center of the longitudinal direction. In other words, the longitudinal direction of each substrate inspection unit 20 extends from the center of the longitudinal direction of the worksite 2 toward the end of the longitudinal direction (the end of the worksite 2). In the worksite 2, the substrate inspection units 20 are symmetrically arranged with respect to the rail 11 as a centerline, and the substrate inspection units 20 are arranged side by side at intervals along the extension direction of the rail 11 (the longitudinal direction of the worksite 2).

Each substrate inspection unit 20, which consists of a plurality of modules, is constructed as a unit for efficiently transferring the substrates W accommodated in the carrier C and performing inspection of the substrates W. Specifically, each substrate inspection unit 20 includes the loader module 30, a transfer module 40 connected to the loader module 30, and a plurality of inspection devices 50 connected to the transfer module 40. Each substrate inspection units 20 unloads the substrate W from the carrier C that has been conveyed to the loader module 30 by the overhead hoist transport device 10, transfers the substrate W to a target inspection device 50 via the transfer module 40, and inspects the substrate W in the inspection device 50.

FIG. 2 is an enlarged plan view illustrating the substrate inspection units 20 and the overhead hoist transport device 10. Next, an example of the substrate inspection units 20 will be described with reference to FIG. 2. In the description of the substrate inspection units 20, positions and directions of the components will be described based on the directions of the arrows illustrated in FIG. 2. The X-axis direction in FIG. 2 is the horizontal direction of the drawing sheet, and extends along the transfer module 40. The Y-axis direction in FIG. 2 is the vertical direction of the drawing sheet and extends along the loader module 30. The Z-axis direction in FIG. 2 is the front-rear direction of the drawing sheet and extends in the height direction of the substrate inspection unit 20.

The loader module 30 of the substrate inspection unit 20 is provided below the rail 11 of the overhead hoist transport device 10 in the vertical direction. The longitudinal direction of the loader module 30 is along the Y-axis direction. In other words, the loader module 30 is installed in such a manner that the longitudinal direction coincides with the rail 11 extending along the Y-axis direction.

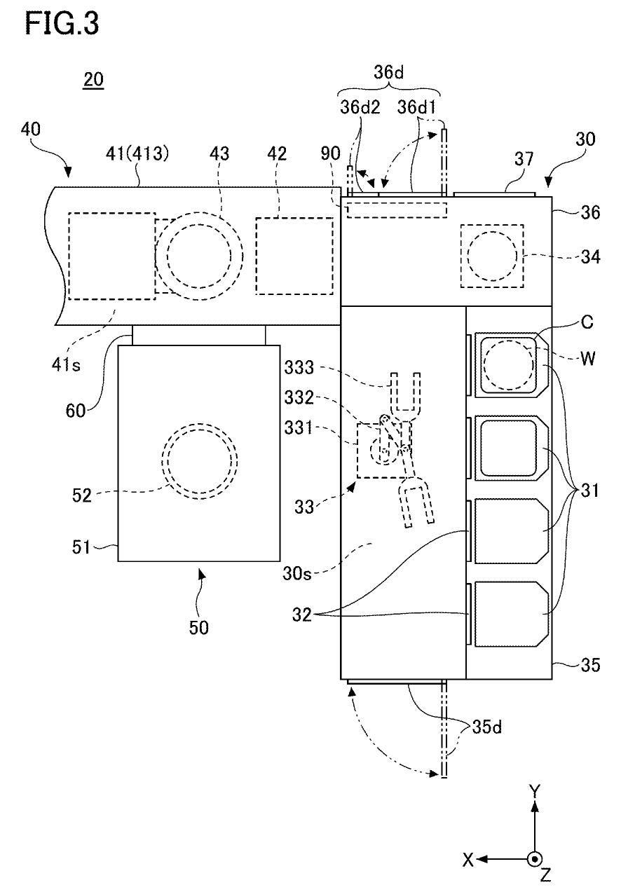

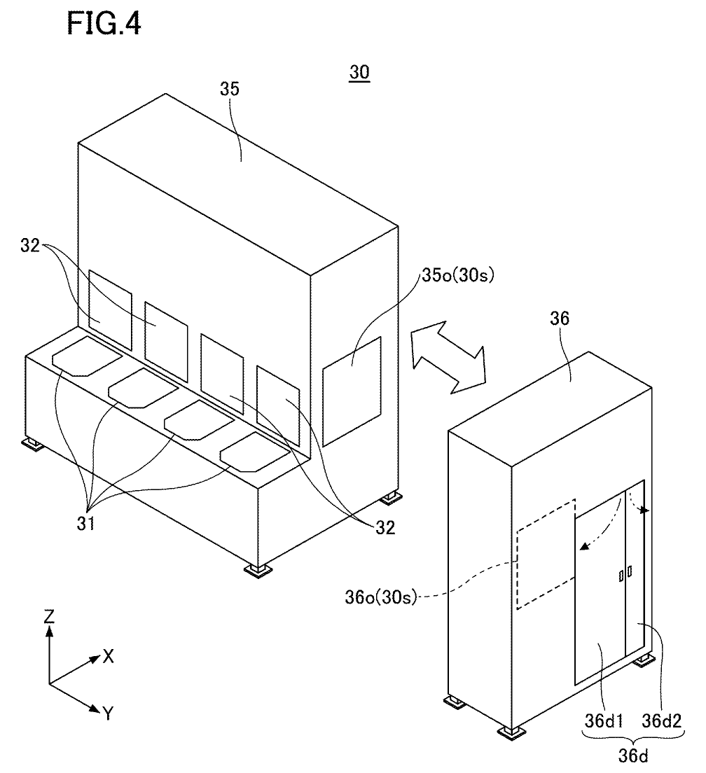

FIG. 3 is a plan view illustrating the loader module 30 and the inspection device 50 in further enlargement. FIG. 4 is a perspective view illustrating a main housing 35 and a sub-housing 36 of the loader module 30. As illustrated in FIGS. 3 and 4, in the loader module 30, a plurality of (4 in FIG. 2) load ports 31 on each of which a plurality of carriers C can be placed are arranged side by side along the Y-axis direction.

The load port 31 of the loader module 30 receives the carrier C from the hoist mechanism of the overhead hoist transport device 10 and delivers the carrier C to the hoist mechanism. The carrier C placed on the load port 31 is fixed by an engagement mechanism (not illustrated) of the load port 31. The wall of the carrier C in the positive X-axis direction is opened when a shutter 32 of the load port 31 is opened, so that the substrate W can be loaded and unloaded.

The loader module 30 is internally provided with a loader-side transfer device 33 for unloading the substrate W accommodated in the carrier C placed at each load port 31 and transferring the substrate W to the transfer module 40. The loader-side transfer device 33 is not particularly limited, but includes, for example, a base portion 331 movable in the longitudinal direction of the loader module 30, a plurality of arms 332 that is rotatable, expandable, and movable up and down relative to the base portion 331, and a fork (end effector) 333 provided in a distal arm of the plurality of arms 332. Although FIG. 3 illustrates the loader-side transfer device 33 provided with two forks 333, the loader-side transfer device 33 may be provided with one or three or more forks 333.

A passage 30s in which the loader-side transfer device 33 moves in the Y-axis direction is provided in the loader module 30. The loader module 30 may be configured such that clean air flows downward into the passage 30s. An aligner 34 may be provided inside the loader module 30 for detecting a position and a circumferential direction (attitude) of the substrate W and adjusting a positional displacement and attitude of the substrate W in cooperation with the loader-side transfer device 33. In the loader module 30 illustrated in FIG. 3, the aligner 34 is provided on the positive Y-axis direction side and the negative X-axis direction side connected to the transfer module 40.

Furthermore, the loader module 30 includes the main housing 35 having the load ports 31, and the sub-housing 36 formed separately from the main housing 35 and relaying between the main housing 35 and the transfer module 40. The main housing 35 and the sub-housing 36 are provided so as to be aligned in the Y-axis direction. For example, the sub-housing 36 is connected to one longitudinal end (positive Y-axis direction) side of the main housing 35. In the loader module 30, while the respective internal frames of the main housing 35 and the sub-housing 36 are formed separately, a cover covering the internal frames may be integrally continuous.

The main housing 35 is formed into a box body having a rectangular shape when viewed from the X-axis direction and an L-shape when viewed from the Y-axis direction by assembling a plurality of frames (not illustrated). The main housing 35 includes the load ports 31 on the upper surface of the step portion of the L-shape. A door 35d is provided on a side wall of the main housing 35 in the negative Y-axis direction so that the passage 30s in the main housing 35 can be accessed during maintenance or the like. The door 35d is a single-hinged door for opening and closing the opening of the main housing 35 by one door plate. During maintenance or the like, an operator can easily access the loader-side transfer device 33 by opening the door 35d.

The sub-housing 36 is formed into a rectangular shape which is long in the X-axis direction and short in the Y-axis direction in a plan view and has a predetermined height in the Z-axis direction by assembling a plurality of frames (not illustrated). The sub-housing 36 is formed smaller than the main housing 35. In the loader module 30 according to the embodiment, the length of the sub-housing 36 in the longitudinal direction (X-axis direction) and the width of the main housing 35 in the short direction (X-axis direction) are made equal to each other. The width of the sub-housing 36 in the Y-axis direction is set to match the width of the transfer module 40 (or to be larger than the width of the transfer module 40).

The sub-housing 36 is provided with the aligner 34. A door 36dis provided on a side wall of the sub-housing 36 in the positive Y-axis direction so that the inside of the sub-housing 36 can be exposed during maintenance or the like. The door 36d is a double hinged door for opening and closing the opening of the sub-housing 36. Specifically, the door 36d has a first door plate 36d1 positioned on the negative X-axis direction side and a second door plate 36d2 positioned on the positive X-axis direction side. The opening of the first door plate 36d1 is opened and closed by rotation when the negative X-axis direction side is supported by a hinge. The opening of the second door plate 36d2 is opened and closed by rotation when the positive X-axis direction side is supported by a hinge. A lock mechanism capable of switching between closing and opening is provided at a boundary between a first door plate 36d1 and a second door plate 36d2.

As illustrated in FIGS. 3 and 4, the width of the second door plate 36d2 (the length along the X-axis direction in the closed state) is shorter than the width of the first door plate 36d1 (the length along the X-axis direction in the closed state). In other words, the first door plate 36d1 can open the opening of the sub-housing 36 to a large extent, while the second door plate 36d2 can open the opening of the sub-housing 36 to a small extent. As a result, the second door plate 36d2 does not largely project outward when opened, and interference with a tester moving mechanism 54, which is described later, can be reliably avoided. The door 36dis not limited to the double-hinged door as described above, and may be a folded door or the like.

A controller 90 for controlling the operation of each component of the substrate inspection unit 20 is provided inside the sub-housing 36. For example, in the substrate inspection unit 20, the controller 90 is arranged at a position adjacent to the door 36d (on the positive Y-axis direction side of the sub-housing 36), so that the controller 90 can be easily accessed when the operator opens the door 36d.

The sub-housing 36 is further provided with a control panel 37 on the side wall facing the positive Y-axis direction, allowing user operation. By arranging the control panel 37 on the positive Y-axis side wall, the need for the operator to access the negative X-axis side where the load ports 31 are located is reduced, thereby minimizing contact between the operator and the carrier C conveyed by the overhead hoist transport device 10.

A passage 30s for the loader-side transfer device 33 is provided inside each of the main housing 35 and the sub-housing 36. The main housing 35 has an opening 35ocommunicating with the passage 30s on a side wall facing the positive Y-axis direction. The sub-housing 36 has an opening 36ocommunicating with the passage 30s on a side wall facing the negative Y-axis direction. In the loader module 30, the opening 35oof the main housing 35 and the opening 36o of the sub-housing 36 are connected so as to communicate with each other, thereby allowing the loader-side transfer device 33 to move between these housings.

In the loader module 30 described above, the main housing 35 of the two housings has versatility and is applicable to various types of devices used as the substrate inspection units 20. In other words, the same main housing 35 can be used even when the type of the substrate inspection unit 20 is changed. On the other hand, the loader module 30 has customizability in that the configuration and shape of the sub-housing 36 of the two housings can be altered according to the needs of each customer. For example, if a customer does not require the aligner 34, the sub-housing 36 can be altered to a specification that does not include the aligner 34. By customizing the sub-housing 36 in this manner while maintaining a common standard for the main housing 35, the loader module 30 can accommodate the needs of various customers while suppressing changes to the specifications of the entire module.

The transfer module 40 is connected to the side wall of the sub-housing 36 of the loader module 30 in the positive direction of the X-axis, and extends linearly along the X-axis direction. In other words, a longitudinal extension direction of the transfer module 40 is orthogonal to the longitudinal extension direction of the loader module 30. As illustrated in FIG. 2, a plurality of (e.g., three) inspection devices 50 are connected to positions on both sides of the transfer module 40 in the extension direction (in other words, a side wall facing the positive Y-axis direction and a side wall facing the negative Y-axis direction). Each of the inspection devices 50 is connected so as to be orthogonal to the extension direction of the transfer module 40 (i.e., at an angle of 90°). However, each of the inspection devices 50 may be connected to the transfer module 40 at an angle of, for example, about 45° to 90° relative to the extension direction of the transfer module 40.

The transfer module 40 receives and transfers the substrate W from and to the loader module 30, transfers the substrate W to a target inspection device 50 among the plurality of inspection devices 50, and transfers and receives the substrate W to and from the stage 52 of the target inspection device 50.

Specifically, the transfer module 40 includes a transfer housing 41 extending along the X-axis direction, a buffer chamber 42 provided on the negative X-axis direction side of the transfer housing 41, and a transfer device 43 reciprocating in the transfer housing 41 along the X-axis direction. The transfer module 40 may be a vacuum transfer module for transferring the substrate W in a state where a transfer space 41s of the transfer housing 41 is reduced to a vacuum atmosphere.

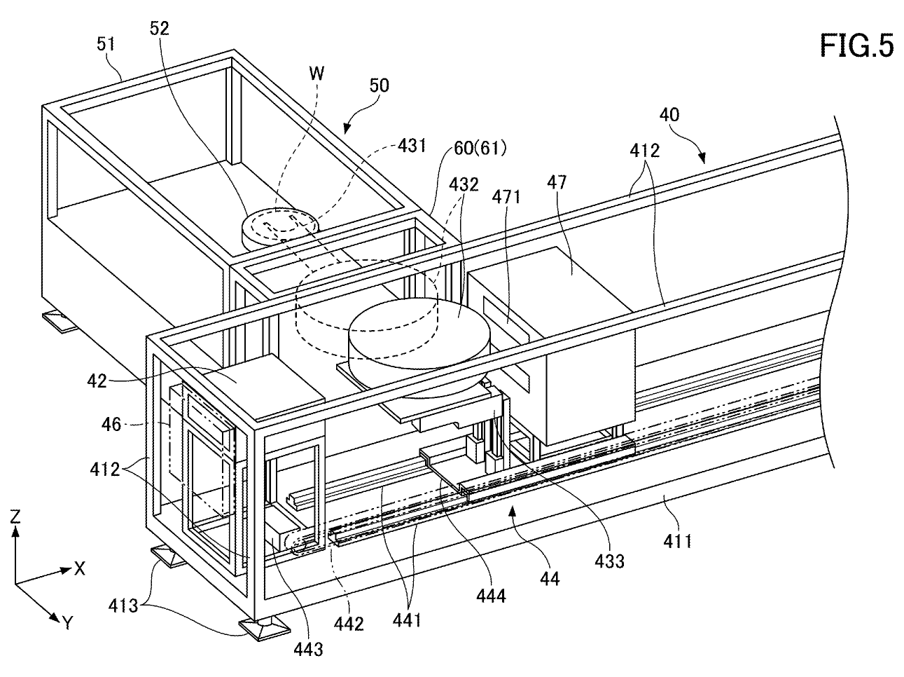

FIG. 5 is an enlarged perspective view illustrating the negative X-axis direction side of the transfer module 40 and the inspection device 50. As illustrated in FIG. 5, a frame structure of the transfer housing 41 is formed by assembling a base plate 411 and a plurality of frames 412. The transfer housing 41 constructs the sealed transfer space 41s by attaching panels (not illustrated) to the base plate 411 and the plurality of frames 412.

The base plate 411 of the transfer housing 41 is fixed to the floor of the worksite 2 via a plurality of leg portions 413. Each of the plurality of leg portions 413 has a level adjuster (not illustrated) capable of adjusting the height in the Z-axis direction. When the transfer module 40 is installed, each level adjuster is adjusted so that the upper surface of the base plate 411 becomes a horizontal plane.

The base plate 411 of the transfer housing 41 is provided with a slide mechanism 44 of the transfer device 43. The slide mechanism 44 includes a pair of rails 441 extending in the X-axis direction, an endless belt 442 extending along the side of the rails 441, a drive source 443 for rotating the belt 442, and a movable body 444 configured to move in accordance with the movement of the belt 442. The movable body 444 serves as a base for supporting the transfer device 43 by bridging the pair of rails 441 and installing the transfer device 43 on its upper surface. The drive source 443 is connected to the controller 90 of the substrate inspection unit 20, and the drive is controlled by the controller 90 to rotate the belt 442 and reciprocate the movable body 444 along the extension direction of the pair of rails 441. The transfer device 43 is not limited to the slide mechanism 44 including the belt 442 and the drive source 443, and various mechanisms may be employed. As an example, the slide mechanism 44 may be configured to slide the movable body 444 by a linear motor.

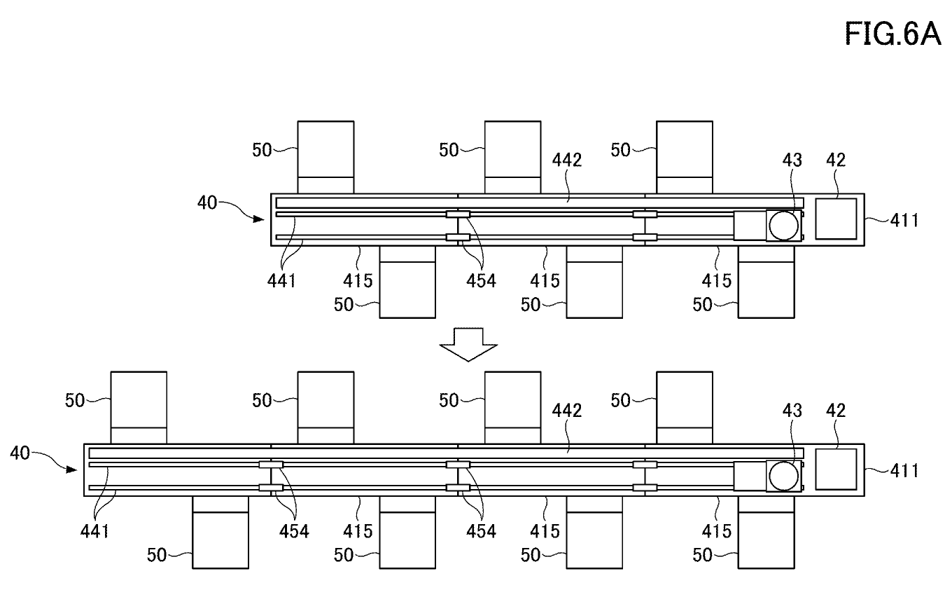

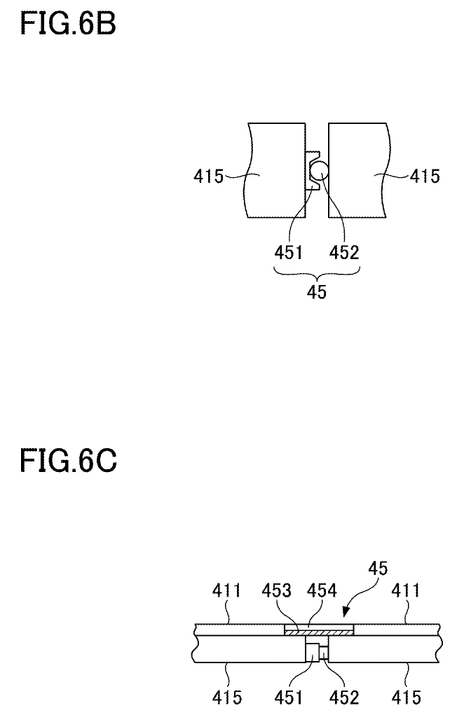

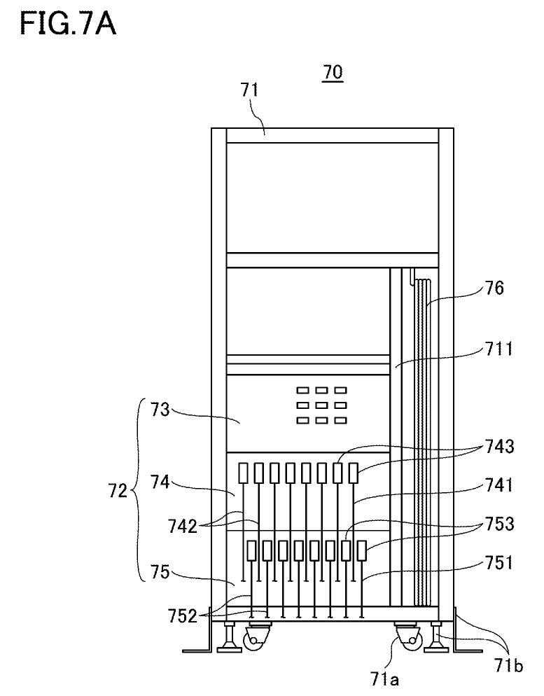

FIG. 6A is a plan view illustrating a function of adjusting the length of the transfer module 40 in an extension direction. FIG. 6B is an enlarged plan view illustrating the connection of the divided frames 415. FIG. 6C is an enlarged side view illustrating the connection of the divided frames 415. As illustrated in FIG. 6A, the transfer module 40 according to the present embodiment is configured to be expandable in the extension direction (X-axis direction).

Specifically, the transfer housing 41 is composed of divided frames 415, the number of which corresponds to the number of inspection devices 50 installed relative to the base plate 411 and the frames 412 (see FIG. 5). A plurality of these divided frames 415 are connected together to form a continuous series. Replacing the belt 442 of the slide mechanism 44 with one corresponding to the moving range of the transfer device 43 (in other words, the number of divided frames 415) allows the transfer device 43 to move over substantially the entire length of the moving range in the X-axis direction. The pair of rails 441 are, for example, installed in advance at a set position for the base plate 411 defined in the divided frame 415 so as to be linearly arranged with respect to the pair of rails 441 of the adjacent divided frame 415. The rails 441 of one divided frame 415 and the rails 441 of the other divided frame 415 are respectively connected by, for example, connecting rails 454.

The divided frames 415 adjacent to each other are connected by an appropriate connecting structure 45. As the connecting structure 45, for example, as illustrated in FIG. 6B, a V-block 451 is provided in one divided frame 415 of the adjacent divided frames 415, and a pin 452 inserted into the V-block 451 is provided in the other divided frame 415. In this case, by inserting the pin 452 into the V-shaped space of the V-block 451, the one divided frame 415 and the other divided frame 415 can be easily positioned. The height of each divided frame 415 (the base plate 411 and the frame 412) can be adjusted by using the level adjuster of the leg portion 413.

As further illustrated in FIG. 6C, the connecting structure 45 is provided with a connecting plate 453 to avoid a direct connection between the base plates 411 supporting the pair of rails 441. The connecting structure 45 may be configured in such a manner that the rails 441 and the connecting rails 454 are connected in a continuous series by fixing the connecting plate 453, to which the connecting rail 454 is previously attached, to each base plate 411.

Referring back to FIG. 5, the buffer chamber 42 provided in the above-described transfer housing 41 is arranged at an appropriate height position by a base 421 mounted on the base plate 411. The buffer chamber 42 temporarily accommodates the substrate W transferred by the loader-side transfer device 33 of the loader module 30 and delivers the substrate W to the transfer device 43. The buffer chamber 42 also temporarily accommodates the substrate W transferred by the transfer device 43 and delivers the substrate W to the loader-side transfer device 33. The buffer chamber 42 may have a load lock function capable of switching the internal space between an atmospheric atmosphere and a vacuum atmosphere.

A gate valve 46 for opening and closing an opening of the buffer chamber 42 is provided on the side wall of the buffer chamber 42 in the negative X-axis direction. Alternatively, the gate valve 46 may be provided on the side wall facing the positive X-axis direction. The substrate inspection unit 20 allows the substrate W to be transferred between the loader module 30 and the buffer chamber 42 by opening the gate valve 46 on the negative X-axis direction side, and allows the inside of the transfer module 40 including the buffer chamber 42 to be decompressed by closing each gate valve 46. The substrate inspection unit 20 also allows the substrate W to be transferred between the transfer device 43 and the buffer chamber 42 by opening the gate valve on the positive X-axis direction side.

The transfer device 43 of the transfer module 40 loads and unloads the substrate W into and from the buffer chamber 42. The transfer device 43 is moved in the X-axis direction by the movable body 444 of the slide mechanism 44 to move to a position at which the transfer device 43 faces a target inspection device 50 among the plurality of inspection devices 50 connected to the transfer module 40. The transfer device 43 advances and enters into the target inspection device 50 that the transfer device 43 faces, and loads and unloads the substrate W into and from that target inspection device 50.

The transfer device 43 includes an end effector 431 for holding the substrate W and an actuator 432 for moving the end effector 431. As an example, the actuator 432 is provided with an extendable and contractable arm (not illustrated) and a shaft part (not illustrated) rotatable about an axis about a base end of the arm. The actuator 432 is provided with an elevating and lowering mechanism 433 capable of elevating and lowering in the Z-axis direction, and the height position of the end effector 431 can be adjusted. The actuator 432 of the transfer device 43 rotates the arm and the end effector 431 through a range of 180° or more. Thus, the transfer device 43 can advance the end effector 431 to the respective inspection devices 50 connected to both side walls of the transfer module 40.

The transfer device 43 may be provided with an accommodating body 47 which runs integrally on the pair of rails 441 and temporarily accommodates the substrate W. For example, the accommodating body 47 is mounted on the movable body 444 of the slide mechanism 44 and arranged in the positive X-axis direction side of the actuator 432. On the side wall facing the actuator 432 on the negative X-axis direction side, the accommodating body 47 includes one or more openings 471 through which the substrate W can be loaded and unloaded into and from the accommodating body 47. The transfer device 43 loads and unloads the substrate W into and from the accommodating body 47 via the openings 471 by rotating, elevating, and lowering the actuator 432 so that the end effector 431 faces the openings 471, and thereafter expanding and contracting the arm.

The accommodating body 47 may also be provided internally with an attitude adjusting device (aligner, not illustrated) for adjusting the position and attitude of the accommodated substrate W in cooperation with the transfer device 43. By providing the attitude adjusting device at a position adjacent to the transfer device 43 in this manner, when a positional displacement or the like occurs in the substrate W, it is possible to reduce a time loss such that the transfer device 43 is moved to re-adjust the positional displacement of the substrate W by the aligner 34. Alternatively, the aligner 34 of the loader module 30 may not be installed in the substrate inspection unit 20.

In addition to moving integrally with the transfer device 43, the accommodating body 47 may be installed at an appropriate position within the transfer module 40. For example, the transfer module 40 may be provided with the accommodating body 47 at an end portion on the positive X-axis direction side (an end portion opposite to the loader module 30).

As illustrated in FIG. 2, the transfer module 40 is provided with a plurality of detection sensors 48 so that the transfer device 43 can recognize its position in the X-axis direction. The plurality of detection sensors 48 may be installed, for example, at positions where the transfer device 43 can transfer the substrate W with respect to each of the plurality of inspection devices 50. However, the position of each detection sensor 48 is not limited to this, and may be installed at equal intervals along the X-axis direction, for example. Alternatively, only one detection sensor 48 may be provided on the path of the transfer device 43. In this case, the position of the transfer device 43 in the X-axis direction can be calibrated based on detection by the single detection sensor 48.

Each detection sensor 48 may be fixed to any of the ceiling, side wall, floor, or the like of the transfer housing 41. An optical sensor capable of optically detecting the presence/absence of the transfer device 43 may be used as the detection sensor 48. For example, the detection sensor 48 may include a light projector for radiating inspection light and a light receiver for receiving reflected light of the inspection light, and output information regarding the presence/absence of the transfer device 43 by detecting a detection surface (not illustrated) installed on the transfer device 43. As long as the position of the transfer device 43 can be detected, the type of the detection sensor 48 is not particularly limited, and may be a distance sensor or the like, or a contact type sensor.

The controller 90 stores information regarding the installation positions (X-axis coordinates) of the plurality of detection sensors 48 along the X-axis direction. The controller 90 recognizes the X-axis coordinates of the transfer device 43 moving in the transfer housing 41 based on the timing when information regarding the presence of the transfer device 43 is acquired by the detection sensor 48 and the previous stored information regarding the X-axis coordinates. The controller 90 can accurately perform position control in the movement of the transfer device 43 based on the recognition of the position of the transfer device 43.

As illustrated in FIG. 5, the inspection devices 50 connected to the above-described transfer module 40 inspect the electrical characteristics of the substrate W transferred by the transfer module 40. The inspection device 50 includes an inspection device housing 51 (only the frame is illustrated in FIG. 5) and a stage 52 for supporting the substrate W in the inspection device housing 51. The stage 52 has a moving mechanism (not illustrated) for moving the substrate W to a target three-dimensional coordinate position.

Referring back to FIG. 2, the inspection device 50 includes a tester 53 above the inspection device housing 51. The tester 53 holds a probe card (not illustrated) having a plurality of probes configured to be in contact with the substrate W and performs inspection of the substrate W. The inspection device 50 further includes the tester moving mechanism 54 for holding the tester 53 and moving the tester 53 between a test position (see the broken line in FIG. 2) and a retracted position (see the two-dot chain line in FIG. 2). A support table 55 for supporting the tester 53 is provided at a retracted position. The inspection device 50 includes, at the time of inspection, components such as a chiller (not illustrated) for adjusting the temperature of the substrate W and a suction mechanism (not illustrated) for reducing the pressure in the inspection device housing 51, which are arranged around the inspection device housing 51 and the tester moving mechanism 54.

Furthermore, the inspection device 50 is connected to the transfer module 40 in an orthogonal direction (at an angle of 90°) via a connecting buffer chamber 60. The connecting buffer chamber 60 disposes the inspection device housing 51 at a position away from the transfer housing 41, so that the tester moving mechanism 54 and the like can be installed without interfering with the transfer housing 41. As illustrated in FIG. 5, the connecting buffer chamber 60 is configured by assembling a plurality of frames 61 and panels (not illustrated). The connecting buffer chamber 60 is formed in a rectangular parallelepiped shape smaller than the actuator 432 of the transfer device 43 of the transfer module 40, and allows the actuator 432 to enter. Although not illustrated, a gate valve for closing the inspection device housing 51 may be provided inside the connecting buffer chamber 60.

In the transfer module 40, the length of the divided frames 415 is set in accordance with the size of the entire inspection device 50 including the inspection device housing 51 and the tester moving mechanism 54 connected to the connecting buffer chamber 60. For this reason, the divided frames 415 are connected along the X-axis direction in the transfer module 40, and the respective inspection devices 50 can be thereby placed at equal intervals.

The loader module 30, the transfer module 40, and the respective inspection devices 50 of the substrate inspection unit 20 require energy, such as electric power, gas supply (positive pressure), and gas suction (negative pressure) for transfer and inspection of the substrate W. The electric power is used for the purpose of operating various components of the substrate inspection unit 20, supplying electric power and signals for inspection to the substrate W, and the like. The suction of gas is used for the purpose of fixing the substrate W in place, and the like. The supply of gas is used for the purpose of cleaning the loader module 30, adjusting the pressure in the space, and the like. Therefore, the substrate inspection unit 20 includes sources of electric power, suction of gas, supply of gas, and the like, and is provided with an energy management device 70 for collectively managing various required energies (distribution, provision, interruption, etc.) as illustrated in FIG. 2. In other words, the respective sources of electric power and the respective components of the substrate inspection unit 20 are connected via a path that is routed through the energy management device 70.

The energy management device 70 is provided, for example, for each of the plurality of substrate inspection units 20 and is installed outside a region where the plurality of inspection devices 50 are arranged (see also FIG. 1). Alternatively, the system of the worksite 2 may be configured such that a single energy management device 70 manages the energy required for a plurality of substrate inspection units 20 (for example, two units). The installation position of the energy management device 70 is not particularly limited, and may be installed, for example, on the loader module 30 side.

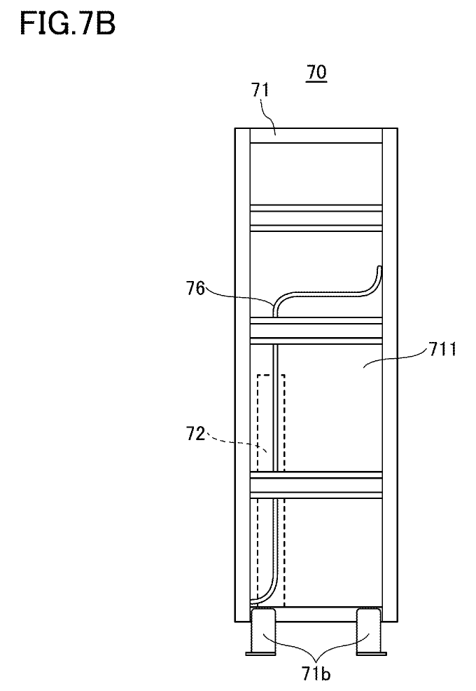

FIG. 7A is a front view illustrating an example of the energy management device 70. FIG. 7B is a side view illustrating an example of the energy management device 70. FIGS. 7A and 7B illustrate a state in which the door of the openable/closable device is removed for convenience of explanation. The energy management device 70 includes a management device housing 71 and an operation panel 72 provided in the management device housing 71 and accessible by an operator with the door open.

The management device housing 71 is formed into a rectangular parallelepiped long in the Z-axis direction (vertical direction) by assembling a plurality of frames and a plurality of panels. A plurality of casters 71a for facilitating the movement of the management device housing 71 and a plurality of fixed bodies 71b for fixing the management device housing 71 to an installation place are provided at the bottom of the management device housing 71. The management device housing 71 accommodates a part of cables and piping connected to a source of the required energy and a part of cables and piping connected to each of the plurality of inspection devices 50. The management device housing 71 has openable and closable doors (not illustrated) on its front and side walls. The doors of the energy management device 70 are closed during operation, and the doors are opened by an operator during installation or maintenance.

The operation panel 72 mounts various devices to be operated by an operator. The operation panel 72 exposes various devices with the front door of the management device housing 71 open. The operation panel 72 is fixed near the front in the management device housing 71 so that the operator can easily access the operation panel 72 with the front door open (see FIG. 7B). The operation panel 72 includes a power distribution panel 73 for distributing electric power, a gas supply distribution panel 74 for distributing gas to be supplied, and a gas suction distribution panel 75 for distributing suction force. The position of the operation panel 72 is not limited to the front wall of the management device housing 71, and may be located at the rear wall, or may be located at the front and rear walls, respectively.

The power distribution panel 73 is provided, for example, at a substantially intermediate position in the vertical direction of the management device housing 71. The power distribution panel 73 is connected to a power generation source (power source) via a main cable 76, and is connected to each components of the substrate inspection unit 20 via a plurality of distribution cables. A power breaker such as a breaker provided in the main cable 76 and each distribution cable is provided at the front surface of the power distribution panel 73. The main cable 76 and the distribution cables accommodated in the management device housing 71 are rotated in a space on the side of the operation panel 72 through a vertical partition wall 711 that partitions the operation panel 72. Thus, the energy management device 70 can reduce interference between the cables and the gas piping.

The gas supply distribution panel 74 is provided, for example, at an adjacent position below the power distribution panel 73. The gas supply distribution panel 74 is connected to a gas generation source (such as a supply pump) through one primary pipe 741, and is connected to each component of the substrate inspection unit 20 through a plurality of secondary pipes 742. A valve 743 for opening and closing the flow paths of the primary pipe 741 and the respective secondary pipes 742, a connector (not illustrated) for connecting the respective secondary pipes 742, and the like are provided on the front surface of the gas supply distribution panel 74. The primary pipes 741 and the respective secondary pipes 742 extend to the outside through the bottom of the management device housing 71.

The gas suction distribution panel 75 is provided, for example, at an adjacent position below the gas supply distribution panel 74 The gas suction distribution panel 75 is connected to a source of suction (such as a suction pump) via a single primary pipe 751, and is connected to each component of the substrate inspection unit 20 via a plurality of secondary pipes 752. A valve 753 for opening and closing the flow paths of the primary pipe 751 and the respective secondary pipe 752, a connector (not illustrated) for connecting the respective secondary pipe 752, and the like are provided on the front surface of the gas suction distribution panel 75. The primary pipe 751 and the respective secondary pipe 752 extend to the outside through the bottom of the management device housing 71.

The energy management device 70 can centrally manage required energy supplies, including power, gas supply, and gas suction. For example, before installing the device main body, an operator can connect the necessary cables and piping by accessing the operation panel 72 once. This reduces labor and shortens the installation period at the start of operation. In addition, the energy management device 70 enables centralized control of supply routes for hazardous energy such as electricity and gas. Furthermore, the energy management device 70 can selectively shut off individual modules when an abnormality occurs, thereby preventing a reduction in operating rate due to maintenance or troubleshooting.

Referring back to FIG. 3, the controller 90 installed in the loader module 30 is composed of a computer having a processor, a memory, an input/output interface, and a communication interface (not illustrated) The controller 90 is connected to the control panel 37, which is a user interface, via an input/output interface.

The control panel 37 has a touch panel, a button, a keyboard and the like as input devices operated by the user. The control panel 37 also has a monitor including a touch panel, a speaker, a lamp and the like as output devices.

The controller 90 transfers the substrate W within the substrate inspection unit 20 by controlling the respective components of the loader module 30 and the transfer module 40 based on content that is input by the operator via the control panel 37. The controller 90 also issues a command to the inspection device 50 which has transferred the substrate W, thereby performing inspection of the substrate W by the inspection device 50.

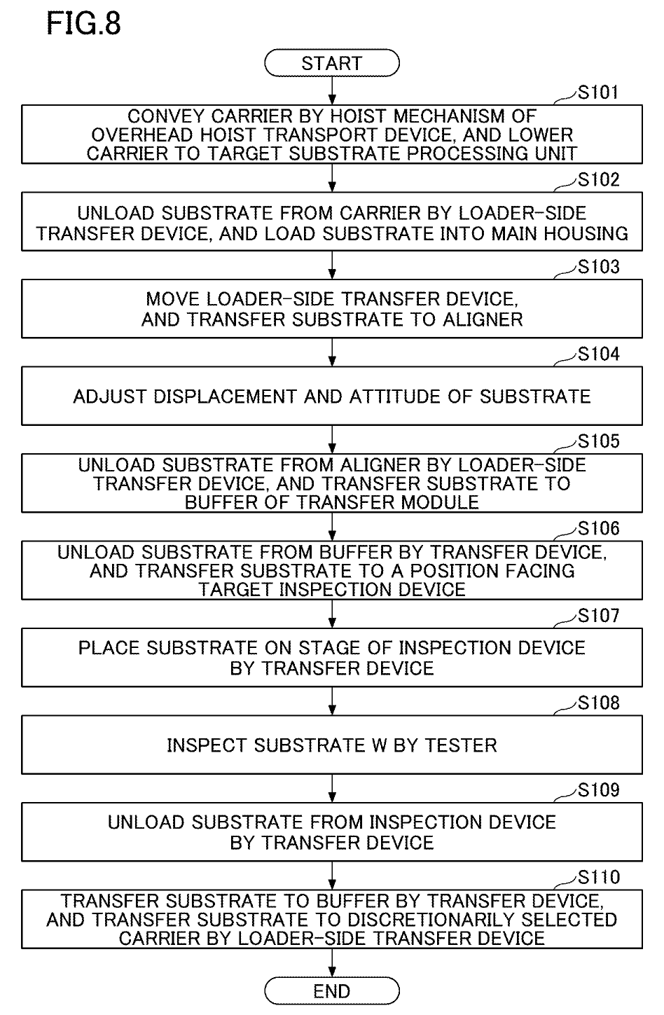

The transfer system 1 according to the present embodiment is basically configured as described above, and its operation (transfer method) will be described below with reference to FIG. 8. FIG. 8 is a flowchart illustrating the transfer method according to an embodiment.

The transfer system 1 performs the processing flow of steps S101 to S110 illustrated in FIG. 8 under the control of the control device 19 of the overhead hoist transport device 10 and the controller 90 of the substrate inspection unit 20.

Specifically, the control device 19 of the overhead hoist transport device 10 conveys the carrier C by the hoist mechanism and places the carrier C in the load port 31 of the target substrate inspection unit 20 (loader module 30) (step S101). For example, the control device 19 previously stores the coordinate position of each load port 31 of each substrate inspection unit 20, reads the coordinate position of the target load port 31, controls the movement of the hoist mechanism, and moves the carrier C just above the load port 31. Thereafter, the control device 19 lowers the carrier C by the hoist mechanism and places the carrier C in the target load port 31, and releases the holding of the carrier C. The controller 90 of the substrate inspection unit 20 acquires information indicating that the carrier C is placed from the load port 31 (or the control device 19) in which the carrier C is placed, and transitions to the transfer of the substrate W in the substrate inspection unit 20.

Specifically, the controller 90 controls the loader-side transfer device 33 of the loader module 30, unloads the substrate W from the carrier C, and loads it into the main housing 35 (step S102). Furthermore, the controller 90 moves the loader-side transfer device 33 to the sub-housing 36, and transfers the held substrate W to the aligner 34 (step S103). Then, the controller 90 controls the aligner 34 and the loader-side transfer device 33 to adjust a positional displacement and attitude of the substrate W (step S104).

Thereafter, the controller 90 unloads the substrate W from the aligner 34 by the loader-side transfer device 33 and loads the substrate W into the buffer chamber 42 of the transfer module 40 (step S105). Therefore, the substrate W whose positional displacement and attitude have been adjusted is accommodated in the buffer chamber 42.

Next, the controller 90 controls the transfer device 43 and the slide mechanism 44 of the transfer module 40 to unload the substrate W from the buffer chamber 42 and transfers the substrate W to a position facing the target inspection device 50 (step S106). In the movement of the transfer device 43, each detection sensor 48 arranged in the X-axis direction detects the presence or absence of the transfer device 43 and transmits detection information to the controller 90. By accurately recognizing the position of the transfer device 43 based on the detection information of each detection sensor 48, the controller 90 can appropriately control the movement of the transfer device 43.

At the position facing the inspection device 50, the controller 90 advances the substrate W into the inspection device housing 51 by the transfer device 43 and places the substrate W on the stage 52 of the inspection device 50 (step S107).

After placing the substrate W, the controller 90 operates the tester 53 of the inspection device 50 to inspect the substrate W by the tester 53 (step S108).

After inspecting the substrate W, the controller 90 again advances the end effector 431 of the transfer device 43 to receive the substrate W placed on the stage 52, and unloads the substrate W from the inspection device 50 (step S109). Then, the controller 90 moves the transfer device 43 to transfer the substrate W to the buffer chamber 42, operates the loader-side transfer device 33 to receive the substrate W placed in the buffer chamber 42, and loads the substrate W into a discretionarily selected carrier C (step S110). Thus, the inspection of the substrate W by the substrate inspection unit 20 is completed.

The substrate inspection unit 20 transfers the plurality of substrates W accommodated in the carrier C to the respective inspection devices 50 for inspection and, after inspection, returns the inspected substrates W to the carrier C. Then, the control device 19 of the overhead hoist transport device 10 controls the hoist mechanism to hold the carrier C accommodating the inspected plurality of substrates W, and raise (detach) the carrier C from the substrate inspection unit 20 and conveys the carrier C along the rail 11.

In the transfer system 1 described above, the loader module 30 of the substrate inspection unit 20 is arranged along the extension direction of the rail 11, enabling smooth placement of the carrier C at a target position in the load port 31. In particular, because the loader module 30 employs a standardized main housing 35, modifications to the configuration of the overhead hoist transport device 10 can be minimized, thereby stabilizing carrier C conveyance. On the other hand, since the sub-housing 36 of the loader module 30 can be customized, the loader module 30 can be readily adapted to customer requirements.

The transfer system 1 and the transfer method of the present disclosure are not limited to the above-described embodiments, and various modified examples are possible. For example, in the embodiment, the transfer system 1 has been described in which the substrate inspection unit 20 having the plurality of inspection devices 50 serving as processing modules is arranged. However, in the transfer system 1, a substrate processing unit having a substrate processing device may be applied instead of a part or all of the substrate inspection unit 20. The substrate processing device may be, for example, a processing module for performing substrate processing, such as film formation, etching, cleaning, bonding, and peeling on the substrate W. The substrate processing device may be a device such as a repair device, a marking device, a reflow device, and an appearance inspection device for processing the substrate W in a process after the substrate W is manufactured. In other words, the transfer system 1 can be applied to a configuration in which the substrate W is transferred to a processing module performing various actions on the substrate W in a process of manufacturing the substrate W.

The transfer target transferred by the transfer system is not limited to the substrate W, and may be, for example, a probe card or a polishing plate. Furthermore, the transfer target may be a consumable member applied to the processing module. An example of the consumable member is a ring (focus ring, edge ring, etc.) arranged around the substrate W in the processing module.

The apparatus for conveying the carrier C is not limited to the overhead hoist transport device 10 conveying the carrier directly above the loader module 30, and may be an apparatus sliding at a position adjacent to the loader module 30 in the horizontal direction. The transfer module 40 is not limited to being connected to the sub-housing 36 on the positive X-axis direction side, and may be connected to the sub-housing 36 on the positive Y-axis direction side, for example.

The technical concept and effects of the present disclosure described in the above embodiments will be described below.

A first aspect of the present disclosure includes the transfer module 40 extending along a first direction, the plurality of processing modules (inspection devices 50) connected to the transfer module 40 and provided along a direction in which the transfer module 40 extends, and the loader module 30 connected to the transfer module 40 and extending along a second direction orthogonal to the first direction. The loader module 30 includes the main housing 35 having the load port 31 configured to load a substrate W into the loader module 30, and the sub-housing 36 formed separately from the main housing 35 and smaller than the main housing 35 and connected to the transfer module 40 in the second direction of the main housing 35. The second direction is a direction parallel to the carrier conveyance line (rail 11) for conveying a carrier C configured to accommodate the substrate W.

According to the above, the transfer system 1 can efficiently transfer the substrate W to the plurality of processing modules (inspection devices 50). Specifically, the transfer system 1 can stably convey the carrier C accommodating the substrate W to the load port 31 of the main housing 35 of the loader module 30. Then, by transferring the substrate W to the transfer module 40 via the sub-housing 36 connected to the main housing 35 in the second direction, the substrate W can be smoothly transferred to a target processing module. In particular, since the transfer system 1 does not need installation of a mechanism for transferring the substrate W from the carrier C to each of the plurality of processing modules, the space efficiency of the whole system can be improved. Since the transfer system 1 has the sub-housing 36 smaller than the main housing 35, the loader module 30 can be easily customized in a small range and can be easily applied to various systems.

The carrier conveyance line (rail 11) extends along the second direction. The transfer module 40, the plurality of processing modules (inspection devices 50), and the loader module 30 form a unit (substrate inspection unit 20), and a plurality of such units are provided at positions on both sides of the carrier conveyance line. Thus, the transfer system 1 can shorten the conveyance distance of the carrier C and more efficiently convey the carrier C to the units.

The sub-housing 36 is internally provided with an aligner 34 configured to adjust a displacement or attitude of the substrate W. Thus, the transfer system 1 can transfer the substrate W whose displacement or attitude has been adjusted in the sub-housing 36 to the transfer module 40.

The sub-housing 36 includes a control panel 37 operable by an operator on a side opposite to a side at which the sub-housing 36 is connected to the main housing 35. Thus, the transfer system 1 can reduce the need for the operator to access the load port 31 side and minimize contact between the carrier C and the operator.

The sub-housing 36 includes a door 36don a side opposite to a side at which the sub-housing 36 is connected to the main housing 35, the door 36d being configured such that, by being on the side, the inside of the sub-housing 36 is exposable. Thus, the transfer system 1 can easily access the inside of the loader module 30 and can efficiently perform maintenance and the like.

The plurality of processing modules (inspection devices 50) are connected to both sides of the transfer module 40 in the second direction. Thus, the transfer system 1 can install a large number of processing modules to the transfer module 40, and further improve the space efficiency.

The plurality of processing modules are inspection devices 50 configured to inspect a substrate W as a transfer target. Thus, the transfer system 1 can efficiently inspect the substrate W by the inspection devices 50.

A second aspect of the present disclosure is the transfer method of a transfer system 1 that includes the transfer module 40 extending along a first direction, the plurality of processing modules (inspection devices 50) connected to the transfer module 40 and provided along a direction in which the transfer module 40 extends, and the loader module 30 connected to the transfer module 40 and extending along a second direction orthogonal to the first direction, and the method includes (A) conveying the carrier C configured to accommodate a substrate W along a direction parallel to the second direction by the carrier conveyance line (rail 11) and placing the carrier C on the load port 31 provided in the main housing 35 of the loader module 30; (B) after the (A), unloading the substrate W from the carrier C placed on the load port 31, transferring the substrate W to the sub-housing 36 formed separately from the main housing 35, the sub-housing 36 being smaller than the main housing 35 and connected to the transfer module 40 in the second direction of the main housing 35, and loading the substrate W into the transfer module 40; and (C) after the (B), transferring the substrate W loaded in the transfer module 40 and transferring the substrate W to any one of the plurality of processing modules (inspection devices 50). Even in this case, the transfer method can efficiently transfer the substrate W to a plurality of processing modules and can improve the space efficiency.

The transfer system 1 and the transfer method according to the embodiments disclosed herein are exemplary and not restrictive in all respects.

The embodiments can be modified and improved in various forms without departing from the scope and gist of the appended claims. The matters described in the above embodiments can be constructed in other ways without contradiction and can be combined without contradiction.

What is claimed is:

1. A transfer system comprising:
a transfer module extending along a first direction;
a plurality of processing modules connected to the transfer module and provided along a direction in which the transfer module extends; and
a loader module connected to the transfer module and extending along a second direction orthogonal to the first direction, wherein
the loader module includes
a main housing having a load port configured to load a transfer target into the loader module; and
a sub-housing formed separately from the main housing and smaller than the main housing and connected to the transfer module in the second direction of the main housing, and
the second direction is a direction parallel to a carrier conveyance line for conveying a carrier configured to accommodate the transfer target.

2. The transfer system according to claim 1, wherein
the carrier conveyance line extends along the second direction, and
the transfer module, the plurality of processing modules, and the loader module form a unit, and a plurality of such units are provided in plurality at positions on both sides of the carrier conveyance line.

3. A transfer system according to claim 1, wherein
the sub-housing is internally provided with an aligner configured to adjust a displacement or attitude of the transfer target.

4. The transfer system according to claim 1, wherein
the sub-housing includes a control panel operable by an operator on a side opposite to a side at which the sub-housing is connected to the main housing.

5. The transfer system according to claim 1, wherein
the sub-housing includes a door on a side opposite to a side at which the sub-housing is connected to the main housing, the door being configured such that, by being on the side, an inside of the sub-housing is exposable.

6. The transfer system according to claim 1, wherein
the plurality of processing modules are connected to both sides of the transfer module in the second direction.

7. The transfer system according to claim 1, wherein
the plurality of processing modules are inspection devices configured to inspect a substrate as the transfer target.

8. A transfer method of a transfer system, the transfer system including
a transfer module extending along a first direction;
a plurality of processing modules connected to the transfer module and provided along a direction in which the transfer module extends; and
a loader module connected to the transfer module and extending along a second direction orthogonal to the first direction, the method comprising:
(A) conveying a carrier configured to accommodate a transfer target along a direction parallel to the second direction by a carrier conveyance line and placing the carrier on a load port provided in a main housing of the loader module;
(B) after the (A), unloading the transfer target from the carrier placed on the load port, transferring the transfer target to a sub-housing formed separately from the main housing, the sub-housing being smaller than the main housing, and connected to the transfer module in the second direction of the main housing, and loading the transfer target into the transfer module; and
(C) after the (B), transferring the transfer target loaded in the transfer module and transferring the transfer target to any one of the plurality of processing modules.
